(19) United States
(12) Patent Application Publication
(10) Pub. No.: US 2008/0290420 A1
(43) Pub. Date: Nov. 27, 2008

(54) SiGe or SiC layer on STI sidewalls

(76) Inventors: Ming-Hua Yu, Jhubei City (TW); Tai-Chun Huang, Hsin-Chu (TW); Chien-Hao Chen, Chuangwei Township (TW); Keh-Chiang Ku, Sindan City (TW); Jr.-Hung Li, Taipei City (TW); Ling-Yen Yeh, Hsin-Chu City (TW); Tze-Liang Lee, Hsin-Chu (TW)

Correspondence Address: SLATER & MATSIL, L.L.P., 17950 PRESTON ROAD, SUITE 1000, DALLAS, TX, 75252, US

(21) Appl. No.: 11/805,894

(22) Filed: May 25, 2007

(51) Int. Cl. H01L 27/092; H01L 21/336; H01L 29/78

(52) U.S. Cl. 257/374; 257/288; 438/197; 257/E27.062; 257/E29.255; 257/E21.409

(57) ABSTRACT

A semiconductor structure includes a semiconductor substrate; an opening in the semiconductor substrate; a semiconductor layer in the opening and covering a bottom and sidewalls of the opening, wherein the semiconductor layer and the semiconductor substrate comprise different materials; and a dielectric material over the semiconductor layer and filling a remaining portion of the opening.

### TECHNICAL FIELD

This invention relates generally to integrated circuits, and more particularly to structures and manufacturing methods of shallow trench isolation regions.

### BACKGROUND

Reductions in sizes and inherent features of semiconductor devices have enabled continued improvements in speed, performance, density, and cost per unit function of integrated circuits over the past few decades. With the continuous scaling of integrated circuits, the conventional methods for improving performance of metal-oxide-semiconductor (MOS) devices, such as shortening gate lengths of MOS devices, has run into bottlenecks. To further enhance the performance of MOS devices, stress may be introduced in the channels of the MOS devices to improve carrier mobility. Generally, it is desirable to induce a tensile stress in the channel region of an n-type MOS (NMOS) device in a source-to-drain direction and to induce a compressive stress in the channel region of a p-type MOS (PMOS) device in a source-to-drain direction.

A commonly used method for applying compressive stress to the channel regions of PMOS devices is to grow SiGe stressors in source and drain regions. Such a method typically includes the steps of forming a gate stack on a semiconductor substrate; forming gate spacers on sidewalls of the gate stack; forming recesses in the silicon substrate along the gate spacers; epitaxially growing SiGe stressors in the recesses; and then annealing. Since SiGe has a greater lattice constant than silicon has, it applies a compressive stress to the channel region, which is located between a source SiGe stressor and a drain SiGe stressor. Similarly, for NMOS devices, stressors that may introduce tensile stresses, such as SiC stressors, may be formed.

Although conventional MOS devices with SiGe stressors or SiC stressors exhibited excellent performance, with the down-scaling of integrated circuits, particularly to 32 nm technology or below, the relaxation effect that occurs on the stresses applied by the SiGe or SiC stressors become increasingly more severe. Hence, the stresses in the resulting MOS devices cannot meet design requirements. Accordingly, new semiconductor structures are needed to continue to provide great stresses to the channel regions of MOS devices with smaller scales.

### SUMMARY OF THE INVENTION

In accordance with one aspect of the present invention, a semiconductor structure includes a semiconductor substrate; an opening in the semiconductor substrate; a semiconductor layer in the opening and covering a bottom and sidewalls of the opening, wherein the semiconductor layer and the semiconductor substrate comprise different materials; and a dielectric material over the semiconductor layer and filling a remaining portion of the opening.

In accordance with another aspect of the present invention, a semiconductor structure includes a semiconductor substrate; a shallow trench isolation (STI) region comprising a dielectric region extending from substantially a top surface of the semiconductor substrate into the semiconductor substrate; an epitaxial liner separating the dielectric region from the semiconductor substrate, wherein the epitaxial liner and the semiconductor substrate have different lattice constants; and a metal-oxide-semiconductor (MOS) device comprising a source/drain region, wherein the source/drain region adjoins the STI region.

In accordance with yet another aspect of the present invention, a semiconductor structure includes a semiconductor substrate; a first shallow trench isolation (STI) region comprising a first dielectric region extending from substantially a top surface of the semiconductor substrate into the semiconductor substrate; a first epitaxial liner separating the first dielectric region from the semiconductor substrate, wherein the first epitaxial liner comprises silicon germanium; a p-type metal-oxide-semiconductor (PMOS) device comprising a first source/drain region, wherein the first source/drain region adjoins the first STI region; a second shallow trench isolation (STI) region comprising a second dielectric region extending from substantially the top surface of the semiconductor substrate into the semiconductor substrate; a second epitaxial liner separating the second dielectric region from the semiconductor substrate, wherein the second epitaxial liner comprises silicon carbon; and an n-type metal-oxide-semiconductor (NMOS) device comprising a second source/drain region, wherein the second source/drain region adjoins the second STI region.

In accordance with yet another aspect of the present invention, a method of forming a semiconductor structure includes providing a semiconductor substrate; forming an opening in the semiconductor substrate; forming a semiconductor layer in the opening and covering a bottom and sidewalls of the opening, wherein the semiconductor layer and the semiconductor substrate comprise different materials; and forming a dielectric material over the semiconductor layer and filling the opening.

In accordance with yet another aspect of the present invention, a method of forming a semiconductor structure includes providing a semiconductor substrate; forming a trench opening in the semiconductor substrate; epitaxially growing a semiconductor layer lining a bottom and sidewalls of the trench opening, wherein the semiconductor layer and the semiconductor substrate comprise different materials; filling a remaining portion of the trench opening left by the semiconductor layer with a dielectric material; and performing a chemical mechanical polish (CMP) to remove excess portions of the dielectric material.

The advantageous features of the present invention include improvements in stress applied to channel regions of MOS device, and the reduction in the stress relaxation effect.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 8 are cross-sectional views of intermediate stages in the manufacturing of an embodiment of the present invention; and

FIG. 9 illustrates an embodiment including a PMOS device and an NMOS device, and adjacent shallow trench isolation (STI) regions.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel shallow trench isolation (STI) structure for providing a stress to channel regions of metal-oxide-semiconductor (MOS) devices and methods of forming the same are provided. The intermediate stages in the manufacturing a preferred embodiment of the present invention are illustrated. The variations of the preferred embodiment are then discussed. Throughout the various views and illustrative embodiments of the present invention, like reference numbers are used to designate like elements.

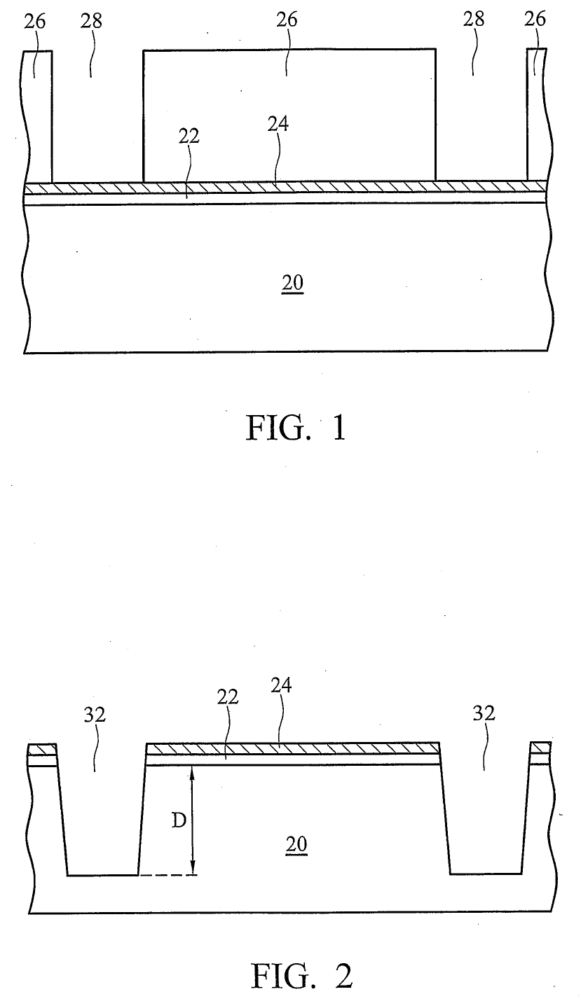

Referring to FIG. 1, semiconductor substrate 20 is provided. In the preferred embodiment, semiconductor substrate 20 includes silicon. Other commonly used materials, such as carbon, germanium, gallium, arsenic, nitrogen, aluminum, indium, and/or phosphorus, and the like, and combinations thereof, may also be included in semiconductor substrate 20. Semiconductor substrate 20 may be formed of single-crystalline or compound materials, and may be a bulk substrate or a semiconductor-on-insulator (SOI) substrate.

Pad layer 22 and mask layer 24 are formed on semiconductor substrate 20. Pad layer 22 is preferably a thin film formed through a thermal process comprising silicon oxide. Pad layer 22 may buffer semiconductor substrate 20 and mask layer 24 so that less stress is generated. Pad layer 22 may also act as an etch stop layer for etching mask layer 24. In the preferred embodiment, mask layer 24 is formed of silicon nitride, for example, using low-pressure chemical vapor deposition (LPCVD). In other embodiments, mask layer 24 is formed by thermal nitridation of silicon, plasma enhanced chemical vapor deposition (PECVD), or plasma anodic nitridation. Photoresist 26 is formed on mask layer 24 and is then patterned, forming openings 28 in photoresist 26.

In FIG. 2, mask layer 24 and pad layer 22 are etched through openings 28, exposing underlying semiconductor substrate 20. The exposed semiconductor substrate 20 is then etched, forming trenches 32. In an exemplary embodiment, the depth D of trenches 32 is between about 2000 Å and about 6000 Å. Photoresist 26 is then removed. Next, a cleaning is preferably performed to remove a native oxide of semiconductor substrate 20. The cleaning may be performed using diluted HF.

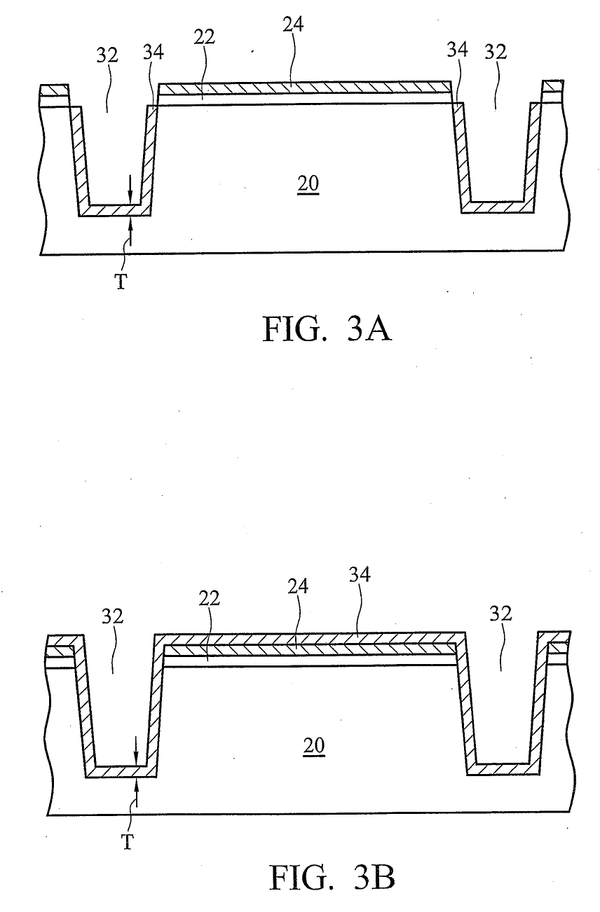

FIGS. 3A and 3B illustrate the formation of compound silicon layer 34 in openings 32, wherein compound silicon layer 34 preferably has a different lattice contact from that of semiconductor substrate 20. In an embodiment, compound silicon layer 34 is a silicon germanium (SiGe) layer. Alternatively, compound silicon (SiC) layer 34 is a silicon carbon layer. Preferably, if germanium is doped, compound silicon layer 34 has a germanium atomic percentage of between about 10 percent and about 40 percent. Otherwise, if carbon is doped, compound silicon layer 34 has a carbon atomic percentage of less than about 2 percent, and more preferably between about 0.5 percent and about 2 percent. Alternatively, compound silicon layer 34 may include other materials having different lattice constants than that of semiconductor substrate 20, such as boron, arsenic, indium, and the like. A portion of compound silicon layer 34 at the bottom of trenches 32 is preferably between about 20 Å and about 500 Å.

The desired material in compound silicon layer 34 preferably depends on the type of MOS devices formed adjacent the compound silicon layer 34. If PMOS devices are formed adjacent compound silicon layer 34, compound silicon layer 34 is preferably a SiGe layer. Conversely, if NMOS devices are formed adjacent compound silicon layer 34, compound silicon layer 34 is preferably a silicon carbon layer.

The formation methods of compound silicon layer 34 preferably include selective epitaxial growth (SEG). In an exemplary embodiment, compound silicon layer 34 is formed using plasma-enhanced chemical vapor deposition (PECVD) in a chamber. The precursors include silicon-containing gases such as SiH₄ and a gas containing germanium, such as GeH₄, if SiGe is to be formed. Conversely, if silicon carbon layer is to be formed, the precursors preferably include the silicon-containing gases and a carbon-containing gas, such as C₂H₄ or C₂H₆. In an exemplary embodiment, compound silicon layers 34 are formed at a temperature of between about 600° C. and about 1000° C., and a pressure of between about 1 torr and about 100 torr.

In an embodiment, as is shown in FIG. 3A, compound silicon layer 34 is selectively formed on the exposed surfaces of silicon substrate 20, but not on exposed surfaces of pad layer 22 and mask layer 24. The selective formation may be achieved by adjusting process conditions, for example, by increasing HCl gas flow to over 30 sccm, or reducing silicon source gas flow. In addition, the process gases may include an etching gas (such as HCl) to remove the compound silicon material undesirably formed on dielectric materials, and hence improving the selectivity.

Compound silicon layer 34 is preferably conformal, and hence process conditions need to be adjusted, for example, by increasing the partial pressure and/or flow rates of precursors, which contain silicon, germanium and/or carbon. Also, if the process gases include the etching gas (such as HCl), the flow rate (or partial pressure) of the etching gas can be reduced to make the deposition process more conformal.

In alternative embodiments, as is shown in FIG. 3B, compound silicon layer 34 is blanket formed on the exposed surfaces of silicon substrate 20 and on exposed surfaces of pad layer 22 and mask layer 24. The blanket formation may be achieved by adjusting process conditions, for example, by reducing HCl gas flow or increasing silicon source gas flow.

FIG. 4 illustrates the filling of trenches 32 with dielectric material 36. Preferably, dielectric material 36 includes silicon oxide formed by high-density plasma (HDP). In other embodiments, dielectric material 36 may be an oxide formed by plasma-enhanced CVD. In yet other embodiments, materials such as silicon oxynitride and silicon nitride may also be used. Dielectric material 36 may include multiple layers, for example, a liner oxide layer, and an additional oxide material on the liner oxide layer, wherein the liner oxide layer and the additional oxide material are formed using different methods, and may be different in compositions.

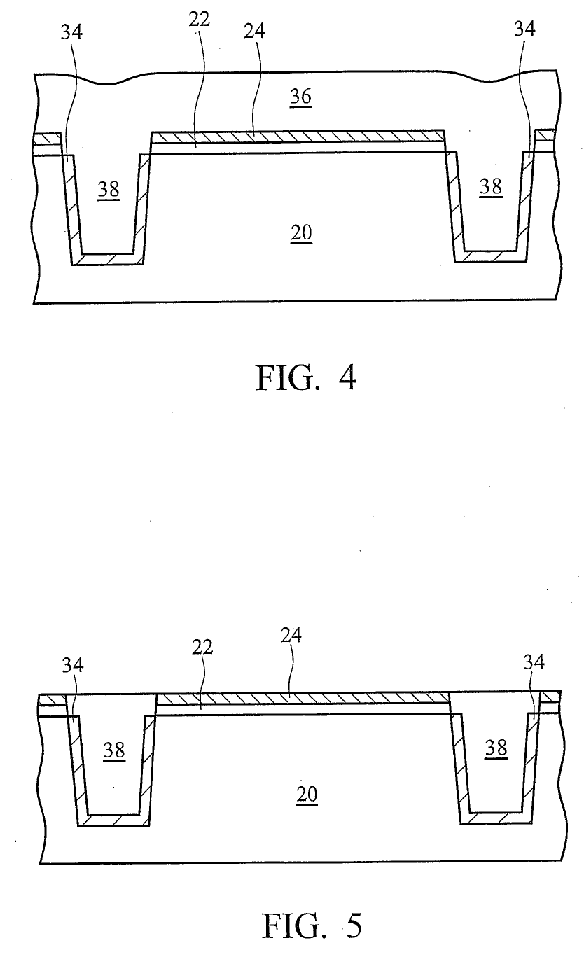

A chemical mechanical polish (CMP) is performed to remove excess dielectric material 36, forming a structure as shown in FIG. 5. Mask layer 24 may act as a CMP stop layer. The remaining portion of dielectric material 36 forms shallow trench isolation (STI) regions 38.

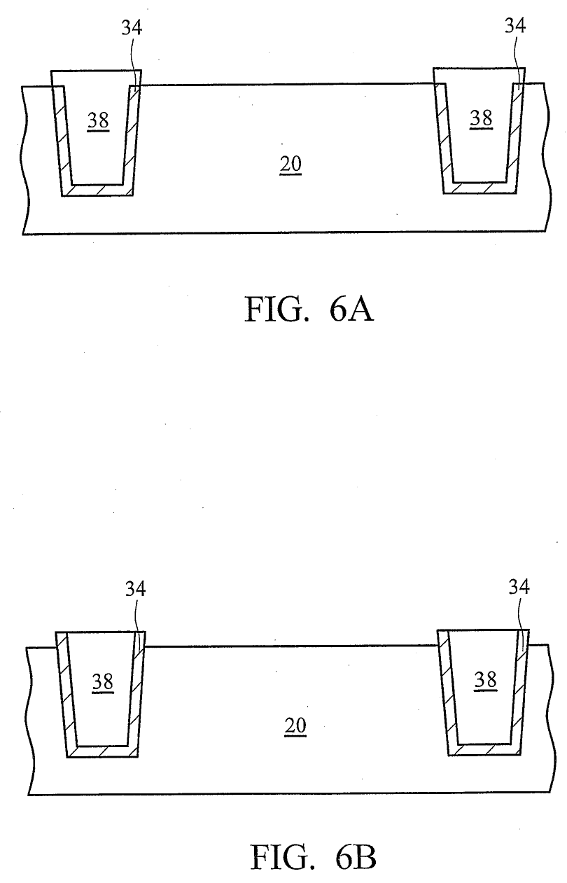

Mask layer 24 and pad layer 22 are then removed, as shown in FIGS. 6A and 6B. Mask layer 24, if formed of silicon nitride, may be removed using wet clean process or hot H₃PO₄, while pad layer 22 may be removed using diluted HF if it is formed of silicon oxide. In the case compound silicon layer 34 is selectively formed, the resulting structure is shown in FIG. 6A, wherein top edges of the remaining portions of compound silicon layer 34 are lower than top surfaces of STI regions 38, and STI regions 38 each have a portion extending over the top edge of the respective portion of compound silicon layer 34. If, however, compound silicon layer 34 is blanket formed, the portions of compound silicon layer 34 on mask layer 24 will be removed during CMP, and the top edges of the remaining portions (also referred to as compound silicon layers 34) of compound silicon layer 34 will substantially level top surfaces of STI regions 38, as is shown in FIG. 6B.

FIG. 7 illustrates the formation of gate dielectric layer 40 and gate electrode layer 42. In an embodiment, gate dielectric layer 40 is a thermal oxide formed in an oxygen-containing environment. In alternative embodiments, gate dielectric layer 40 may be formed of high-k dielectric materials having k values greater than about 3.9. Gate electrode layer 42 preferably includes polysilicon, although it may be formed of other conductive materials, such as metals, metal silicides, metal nitrides, and the like.

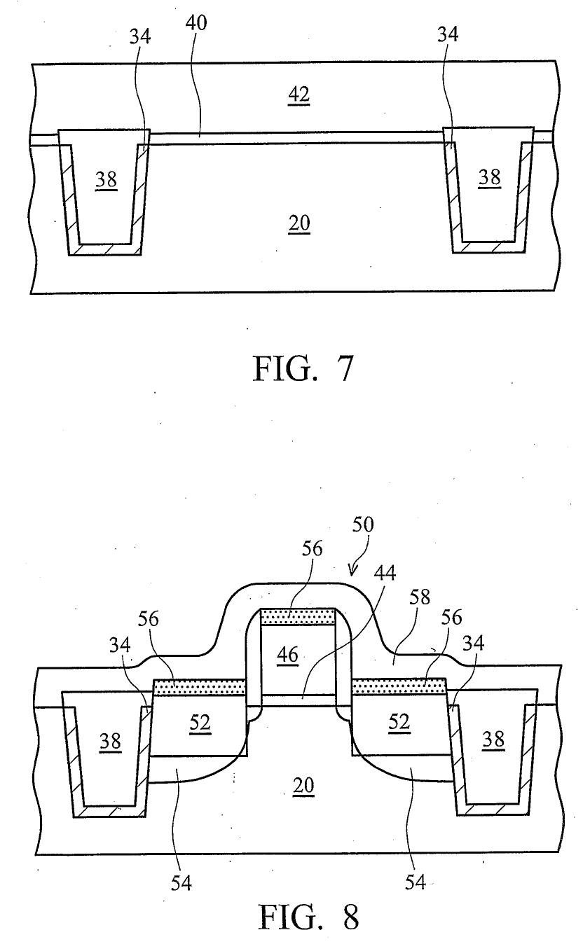

Referring to FIG. 8, gate dielectric layer 40 and gate electrode layer 42 are patterned, forming gate dielectric 44 and gate electrode 46 of MOS device 50, respectively. MOS device 50 also includes other components, such as stressors 52, source/drain regions 54, and silicide regions 56. Etch stop layer 58 may be formed over MOS device 50. The details for forming MOS device 50 are well known in the art, and thus are not repeated herein.

Compound silicon layers 34, stressors 52 and etch stop layer 58 preferably have same type of stresses. In the embodiment wherein MOS device 50 is a PMOS device, compound silicon layer 34 and stressors 52 are preferably formed of SiGe, and thus apply compressive stresses to the channel region of MOS device 50. Conversely, if MOS device 50 is an NMOS device, compound silicon layer 34 and stressors 52 are preferably formed of SiC, and thus apply tensile stresses to the channel region of MOS device 50.

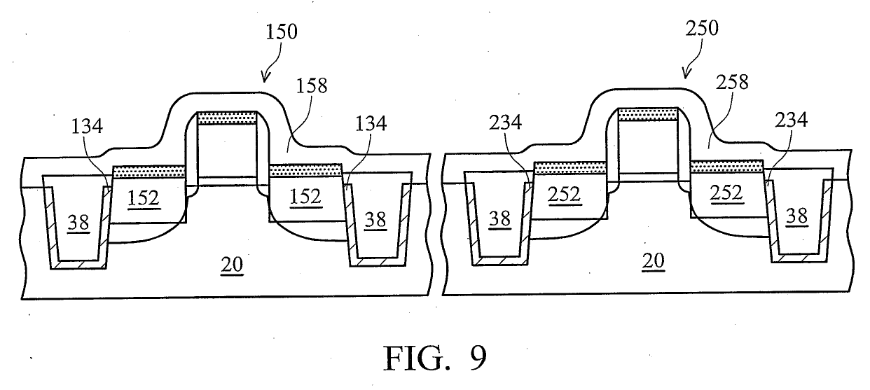

FIG. 9 illustrates an embodiment including a PMOS device and an NMOS device. PMOS device 150 includes stressors 152 for applying a compressive stress to its channel region. Stressors 152 are preferably formed of SiGe. NMOS device 250 includes stressors 252 for applying a tensile stress to its channel region. Stressors 252 are preferably formed of SiC. Preferably, SiGe layer 134 is formed in STI regions adjacent PMOS device 150, while SiC layer 234 is formed in STI regions adjacent NMOS device 250. ESLs 158 and 258 preferably apply a compressive and a tensile stress to the underlying MOS devices 150 and 250.

The formation of compound silicon layer 34 improves the stress applied to channel region of MOS device 50 (refer to FIG. 8). Simulation results have revealed that if stressors 52 are formed of SiGe with 20 percent germanium, and if no compound silicon layer 34 is formed, the compressive stress in the channel region of a sample MOS device is about 694 MPa. However, if compound silicon layers 34 with 25 percent germanium, and 300 Å thickness are added, the compressive stress in the channel region of the sample MOS device is increased to about 881 MPa, which is about 27% improvement.

An advantageous feature of the present invention's embodiments is that by forming compound silicon layer 34 underlying STI regions 38, the stress generated by compound silicon layer 34 is less relaxed. Experiment results indicated that for a 300 mm wafer, wherein STI regions and the underlying SiGe regions occupy about 20 percent of the wafer area, after 1000° C. annealing, the bow height of the wafer is about 40 μm. However, for a similar wafer, where no oxide regions 38 are filled in the STI trenches, the bow height of the wafer is reduced to less than about 10 μm after the annealing. This indicates that the STI regions 38 have the effect of preserving the stress generated by the compound silicon layer 34. Therefore, the stress applied by compound silicon layer 34 is less likely to be relaxed than the stress applied by stressors 52 (refer to FIG. 9) in subsequently applied high temperatures.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a semiconductor substrate;
an opening in the semiconductor substrate;
a semiconductor layer in the opening and covering a bottom and sidewalls of the opening, wherein the semiconductor layer and the semiconductor substrate comprise different materials; and
a dielectric material over the semiconductor layer and filling a remaining portion of the opening.

2. The semiconductor structure of claim 1, wherein the semiconductor layer comprises an epitaxial material selected from the group consisting essentially of silicon germanium and silicon carbon.

3. The semiconductor structure of claim 2, wherein the silicon germanium comprises between about 20 atomic percent and about 30 atomic percent germanium.

4. The semiconductor structure of claim 2, wherein the silicon carbon comprises less than about 2 atomic percent carbon.

5. The semiconductor structure of claim 1, wherein the semiconductor layer is substantially conformal.

6. The semiconductor structure of claim 1, wherein the semiconductor layer has a top edge substantially level with a top surface of the dielectric material.

7. The semiconductor structure of claim 1, wherein the semiconductor layer has a top edge lower than a top surface of the dielectric material, and wherein the dielectric material extends on the top edge of the semiconductor layer.

8. The semiconductor structure of claim 1 further comprising a metal-oxide-semiconductor (MOS) device comprising a stressor, wherein the stressor adjoins the semiconductor layer, and wherein the stressor and the semiconductor layer have a same type of inherent stress.

9. A semiconductor structure comprising:
a semiconductor substrate;
a shallow trench isolation (STI) region comprising a dielectric region extending from substantially a top surface of the semiconductor substrate into the semiconductor substrate;
an epitaxial liner separating the dielectric region from the semiconductor substrate, wherein the epitaxial liner and the semiconductor substrate have different lattice constants; and
a metal-oxide-semiconductor (MOS) device comprising a source/drain region, wherein the source/drain region adjoins the STI region.

10. The semiconductor structure of claim 9, wherein the MOS device further comprises a source/drain stressor, and wherein the source/drain stressor and the epitaxial liner apply a same type of stress to a channel region of the MOS device.

11. The semiconductor structure of claim 9, wherein the epitaxial liner is substantially conformal.

12. The semiconductor structure of claim 9, wherein the epitaxial liner extends to a top surface of the STI region.

13. The semiconductor structure of claim 9, wherein a top edge of the epitaxial liner is lower than a top surface of the STI region.

14. The semiconductor structure of claim 9, wherein the epitaxial liner comprises a material selected from the group consisting essentially of silicon germanium and silicon carbon.

15. The semiconductor structure of claim 9 further comprising an etch stop layer over the MOS device, wherein the etch stop layer and the epitaxial liner apply a same type of stress to a channel region of the MOS device.

16. A semiconductor structure comprising:
a semiconductor substrate;
a first shallow trench isolation (STI) region comprising a first dielectric region extending from substantially a top surface of the semiconductor substrate into the semiconductor substrate;
a first epitaxial liner separating the first dielectric region from the semiconductor substrate, wherein the first epitaxial liner comprises silicon germanium;
a p-type metal-oxide-semiconductor (PMOS) device comprising a first source/drain region, wherein the first source/drain region adjoins the first STI region;
a second shallow trench isolation (STI) region comprising a second dielectric region extending from substantially the top surface of the semiconductor substrate into the semiconductor substrate;
a second epitaxial liner separating the second dielectric region from the semiconductor substrate, wherein the second epitaxial liner comprises silicon carbon; and
an n-type metal-oxide-semiconductor (NMOS) device comprising a second source/drain region, wherein the second source/drain region adjoins the second STI region.

17. The semiconductor structure of claim 16, wherein the silicon germanium comprises between about 20 percent and about 30 percent germanium, and wherein the silicon carbon comprises less than about 2 percent carbon.

18. The semiconductor structure of claim 16, wherein the PMOS device further comprises a silicon germanium stressor, and wherein the NMOS device further comprises a silicon carbon stressor.

19. The semiconductor structure of claim 16, wherein the first and the second epitaxial liners are substantially conformal.

20. A method of forming a semiconductor structure, the method comprising:
providing a semiconductor substrate;
forming an opening in the semiconductor substrate;
forming a semiconductor layer in the opening and covering a bottom and sidewalls of the opening, wherein the semiconductor layer and the semiconductor substrate comprise different materials; and
forming a dielectric material over the semiconductor layer and filling the opening.

21. The method of claim 20, wherein the step of forming the semiconductor layer comprises epitaxial growth.

22. The method of claim 20, wherein the step of forming the semiconductor layer comprises a blanket formation.

23. The method of claim 20, wherein the step of forming the semiconductor layer comprises a selective formation.

24. The method of claim 20, wherein the semiconductor layer is substantially conformal.

25. The method of claim 20 further comprising forming a metal-oxide-semiconductor (MOS) device, wherein the MOS device comprises a source/drain region adjoining the semiconductor layer.

26. The method of claim 25, wherein the step of forming the MOS device further comprises forming a source/drain stressor adjoining the semiconductor layer, and wherein the semiconductor layer and the source/drain stressor have a same type of inherent stress.

27. The method of claim 20, wherein the semiconductor layer comprises a material selected from the group consisting essentially of silicon carbon and silicon germanium.

28. A method of forming a semiconductor structure, the method comprising:
providing a semiconductor substrate;
forming a trench opening in the semiconductor substrate;
epitaxially growing a semiconductor layer lining a bottom and sidewalls of the trench opening, wherein the semiconductor layer and the semiconductor substrate comprise different materials;
filling a remaining portion of the trench opening left by the semiconductor layer with a dielectric material; and
performing a chemical mechanical polish (CMP) to remove excess portions of the dielectric material.

29. The method of claim 28, wherein the semiconductor layer comprises a material selected from the group consisting essentially of silicon germanium and silicon carbon.

30. The method of claim 28 further comprising forming a pad layer and a mask layer before the step of forming the trench opening, and removing the pad layer and the mask layer after the CMP.

31. The method of claim 30, wherein the semiconductor layer is selectively formed only on exposed surfaces of the silicon substrate in the trench opening.

32. The method of claim 30, wherein the semiconductor layer is blanket formed in the trench opening and on the mask layer.

33. The method of claim 28 further comprising forming a metal-oxide-semiconductor (MOS) device, wherein the MOS device comprises a source/drain region adjoining the semiconductor layer.
